(19) United States
(12) Patent Application Publication
(10) Pub. No.: US 2025/0022754 A1
(43) Pub. Date: Jan. 16, 2025

(54) METHOD OF MANUFACTURING SEMICONDUCTOR DEVICE

(71) Applicant: Mitsubishi Electric Corporation, Tokyo (JP)

(72) Inventors: Minori MATSUOKA, Tokyo (JP); Kosuke MIYAZAKI, Tokyo (JP); Kenichi HAMANO, Tokyo (JP)

(73) Assignee: Mitsubishi Electric Corporation, Tokyo (JP)

(21) Appl. No.: 18/625,543

(22) Filed: Apr. 3, 2024

(30) Foreign Application Priority Data
Jul. 14, 2023 (JP) 2023-115862

(51) Int. Cl. H01L 21/78; H01L 21/66

(52) U.S. Cl. CPC H01L 21/78; H01L 22/32

(57) ABSTRACT

An object is to provide a technique that can suppress peeling of a coating film while reducing an ineffective region. A method of manufacturing a semiconductor device includes a preparation step of preparing a semiconductor structure and a dicing step in which dicing is performed on the dicing line region. A thickness of the side monitor electrode is smaller than a thickness of the coating film, and 15>b>1.15×d+6.88 is established between a distance b [μm], being a distance between the coating film and the side monitor electrode, and a length d [mm], being a length of the side monitor electrode in an extending direction of the dicing line region in plan view.

### BACKGROUND OF THE INVENTION

### Field of the Invention

The present disclosure relates to a method of manufacturing a semiconductor device.

### Description of the Background Art

A semiconductor chip in which a coating film is provided in a termination region has been proposed. Such a semiconductor chip has a problem in that, after the coating film is formed using a developer, when the developer remains in a concave portion adjacent to the coating film, the coating film may be peeled off by the developer. On the other hand, International Publication No. 2014/013581 proposes a technique for suppressing peeling of the coating film by coating the concave portion with the coating film and suppressing remaining of the developer.

When the coating film is provided near the dicing line, a possibility is there that the coating film would be caught during dicing using a blade. For this reason, the coating film needs to be provided a certain distance away from the dicing line. However, when an opening is provided as in the technique of International Publication No. 2014/013581, the distance between the coating film and the dicing line needs to make larger than the above-mentioned certain distance. As a result, a problem is posed in that an ineffective region on a semiconductor substrate is enlarged, increasing the manufacturing cost of the semiconductor device. Further, when a side monitor electrode is provided for monitoring the electrical characteristics of a semiconductor chip during a manufacturing process, a problem is posed in that an ineffective region on a semiconductor substrate is enlarged, increasing the manufacturing cost of the semiconductor device.

### SUMMARY

The present disclosure has been made in view of the above-mentioned problems and an object thereof is to provide a technique that can suppress peeling of a coating film while reducing an ineffective region.

According to the present disclosure, a method of manufacturing a semiconductor device includes a preparation step of preparing a semiconductor structure in which a termination region of a semiconductor chip and a dicing line region adjacent to the termination region in plan view are defined, and a dicing step in which dicing is performed on the dicing line region, in which the semiconductor structure includes a semiconductor substrate in which the termination region and the dicing line region are defined, a side monitor electrode provided on the semiconductor substrate in the dicing line region, a passivation film provided from an upper portion of the semiconductor substrate in the termination region to an upper portion of the side monitor electrode, and a coating film provided on the passivation film in the termination region, a thickness of the side monitor electrode is smaller than a thickness of the coating film, and 15>b>1.15×d+6.88 is established between a distance b [μm], being a distance between the coating film and the side monitor electrode, and a length d [mm], being a length of the side monitor electrode in an extending direction of the dicing line region in plan view.

Peeling of a coating film can be suppressed while reducing an ineffective region.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing a configuration of a semiconductor structure according to Embodiment 1;

FIG. 2 is a plan view showing the configuration of the semiconductor structure according to Embodiment 1;

FIG. 3 is a cross-sectional view showing the configuration of the semiconductor structure according to Embodiment 1;

FIG. 4 is a graph showing experimental results on the semiconductor structure according to Embodiment 1;

FIG. 5 is a cross-sectional view showing a configuration of a semiconductor structure according to Embodiment 2;

FIG. 6 is a plan view showing the configuration of the semiconductor structure according to Embodiment 2;

FIG. 7 is a plan view showing the configuration of a semiconductor structure according to Modification of Embodiment 2;

FIG. 8 is a cross-sectional view showing the configuration of the semiconductor structure according to Modification of Embodiment 2; and

FIG. 9 is a cross-sectional view showing the configuration of the semiconductor structure according to Modification of Embodiment 2.

### DESCRIPTION OF THE PREFERRED EMBODIMENTS

Embodiments will be described below with reference to the accompanying drawings. The features described in each Embodiment below are illustrative, and not all features are necessarily essential. Also, in the description given below, the same or similar reference numerals are given to the same components in a plurality of Embodiments, and different components will be mainly explained. Also, in the following description, terms indicating specific positions or directions such as “upper”, “lower”, “left”, “right”, “front”, and “back” may not necessarily coincide with the positions or directions at the time of implementation.

### Embodiment 1

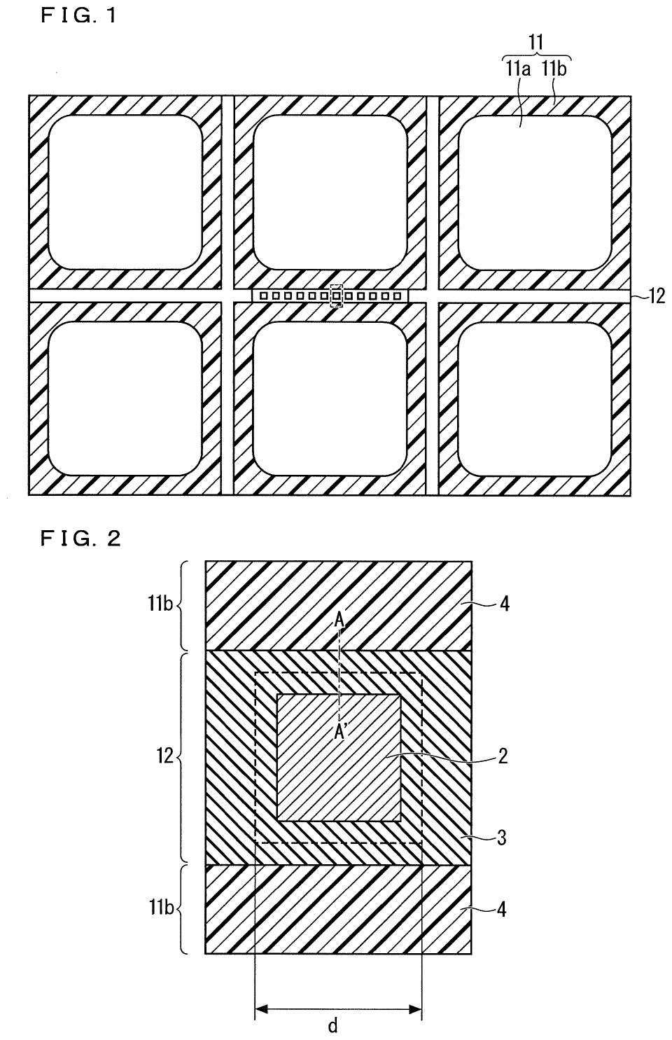

FIG. 1 is a plan view showing a configuration of a semiconductor structure according to Embodiment 1. The semiconductor structure is prepared during a preparation step of the semiconductor structure during the manufacturing process of the semiconductor device. A cell structure region 11a and a termination region 11b of a semiconductor chip 11, and a dicing line region 12 are defined in the semiconductor structure.

A semiconductor element is provided in the cell structure region 11a. The semiconductor element includes, at least one of, for example, a metal oxide semiconductor field effect transistor (MOSFET), an insulated gate bipolar transistor (IGBT), a reverse conducting-IGBT (RC-IGBT), a Schottky barrier diode (SBD), and a PN junction diode (PND). In the present specification, for example, “at least one of A, B, C, . . . , and Z” refers to one of all combinations of one or more extracted from groups of A, B, C, . . . , and Z.

The termination region 11b is a region surrounding the cell structure region 11a in plan view, and is a region that maintains the breakdown voltage of the cell structure region 11a.

The dicing line region 12 is a region provided between adjacent semiconductor chips 11 in plan view and adjacent to the termination region 11b of each semiconductor chip 11. The semiconductor chips 11 are separated and individualized by a dicing step in which dicing is performed in the dicing line region 12 of the semiconductor structure. The width of the dicing line region 12 is typically, for example, 80 to 120 μm in order to secure a width through which a dicing blade such as a grindstone blade passes.

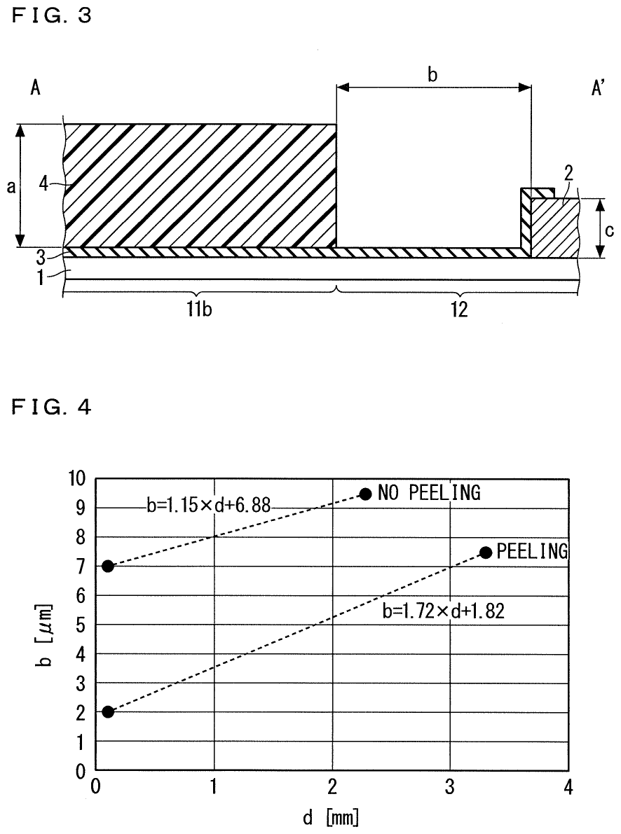

FIG. 2 is an enlarged plan view of the portion surrounded by the broken line in FIG. 1, and FIG. 3 is a cross-sectional view taken along line A-A′ in FIG. 2. As shown in FIGS. 2 and 3, the semiconductor structure includes a semiconductor substrate 1, a side monitor electrode 2, a passivation film 3, and a coating film 4.

The semiconductor substrate 1 in FIG. 3 is composed of silicon (Si) or a wide bandgap semiconductor, for example, and includes at least one of a regular semiconductor wafer and an epitaxially grown layer. A wide bandgap semiconductor includes, for example, silicon carbide (SiC), gallium nitride (GaN), diamond, and the like. When the semiconductor substrate 1 is composed of a wide bandgap semiconductor, stable operation of the semiconductor element at high temperatures and high voltages and increased switching speed are enabled. However, due to the high price of the semiconductor substrate 1 composed of SiC, reduction in the ineffective region in the semiconductor substrate 1 as much as possible is required from the viewpoint of reducing the cost of the semiconductor device. In contrast, as described below, according to Embodiment 1, the reduction in the ineffective region in the semiconductor substrate 1 is enabled.

The semiconductor chips 11 shown in FIG. 1 are provided on the semiconductor substrate 1, and the cell structure regions 11a, the termination regions 11b, and the dicing line region 12 are defined in the semiconductor substrate 1. A front surface electrode of the semiconductor chip 11 is formed on the front surface of the semiconductor substrate 1, and a back surface electrode of the semiconductor chip 11 is formed on the back surface 25 of the semiconductor substrate 1. Note that the back surface of the semiconductor substrate 1 may be ground before forming the back electrode.

As shown in FIG. 3, the side monitor electrode 2 is provided on the semiconductor substrate 1 in the dicing line region 12. The side monitor electrode 2 is provided to detect abnormalities during the manufacturing process of the semiconductor device. For example, a diffusion layer is provided in the semiconductor substrate 1 under the side monitor electrode 2, and the diffusion layer is formed simultaneously with a cell diffusion layer constituting the semiconductor element of the cell structure region 11a. Before dicing, an operator can detect abnormalities in the manufacturing process at a relatively early stage by electrically connecting a probe and the side monitor electrode 2 to measure the resistance of the diffusion layer under the side monitor electrode 2. Further, should the operator discover a characteristic defect in the semiconductor chip 11 and analyzes the measured value of the side monitor electrode 2, retroactive identification of an abnormal step can be implemented. Further, the operator can also implement line management by comparing the changes in characteristic values obtained from the side monitor electrode 2.

The side monitor electrode 2 is provided at at least one location in the dicing line region 12 within an exposure shot. Although depending on the size of the semiconductor chip 11, it is preferable that a plurality of side monitor electrodes 2 be provided in a size that fits on one side of the semiconductor chip 11. In many cases, marks for alignment during the exposure process are provided at the intersections where paths in the dicing line region 12 intersect; therefore, it is preferable that the side monitor electrodes 2 not be provided at the intersections. Note that the side monitor electrode 2 is composed of AlSi, for example.

The passivation film 3 is provided from the upper portion of the semiconductor substrate 1 in the termination region 11b to the upper portion of the side monitor electrode 2. The passivation film 3 provided as an insulating film on the semiconductor substrate 1 in the termination region 11b has a function of suppressing creeping discharge of the semiconductor chip 11, similar to the coating film 4 described later. The passivation film 3 is provided with an opening that partially exposes the upper portion of the side monitor electrode 2 that is electrically connected to the probe. For example, the pattern of the passivation film 3 is formed by depositing a silicon oxide film or a nitride film on the upper surface of the semiconductor substrate 1, and then subjecting to etching the silicon oxide film or the nitride film through a resist using a photolithography process.

The coating film 4 is provided on the passivation film 3 in the termination region 11b . If the coating film 4 is caught in the grindstone blade during dicing, clogging may reduce the productivity, or chipping may occur at the edge of the semiconductor chip 11. For this reason, as shown in FIGS. 2 and 3, the coating film 4 exposes the passivation film 3 in the dicing line region 12.

The coating film 4 is composed of, for example, photosensitive polyimide. The pattern of the coating film 4 is formed by a developing step included in the preparation step of the semiconductor structure. For example, the coating film 4 is formed by applying a photosensitive polyimide precursor solution onto the semiconductor substrate 1 provided with the passivation film 3, subjecting to prebaking, forming into an arbitrary pattern by a photolithography process, and then subjecting main baking. Photosensitive polyimide is applied to a wafer and then selective exposure is performed using a mask, thereby the exposed portions being melted by a developer, forming the coating film 4 in any desired pattern.

The coating film 4 provided as an insulating film on the passivation film 3 in the

termination region 11b has a function of suppressing creeping discharge of the semiconductor chip 11. Further, the coating film 4, which is composed of polyimide, having flexibility has a function of protecting the structure of the termination region 11b of the semiconductor chip 11 from stress caused by expansion and contraction of an external sealing material or the like. Note that after the back surface of the semiconductor substrate 1 is ground so that the thickness of the semiconductor substrate 1 is, for example, about 100 μm or less, the warpage of the semiconductor substrate 1 after a grinding step becomes large, this makes it difficult to form the passivation film 3 or the coating film 4. For this reason, the formation of the passivation film 3 or the coating film 4 is preferably performed before the grinding step of the semiconductor substrate 1.

According to the above configuration, the side monitor electrode 2 is provided on the dicing line region 12; therefore, a dedicated region for the side monitor electrode 2 is not required. Accordingly, the ineffective region in the semiconductor substrate 1 can be reduced. However, as shown in FIG. 3, a concave portion is formed between the side monitor electrode 2 and the coating film 4, this leaves a possibility that the coating film 4 peels off with the developer used to form the coating film 4 remaining in the concave portion. Therefore, the inventor conducted an experiment to study a configuration in which the coating film 4 does not peel off.

FIG. 4 is a graph showing the experimental results. In the experiment, the thickness c, representing the thickness of the side monitor electrode 2, is smaller than the thickness a, representing the thickness of the coating film 4, the distance b [μm], representing the distance between the coating film 4 and the side monitor electrode, and the length d [mm], representing the length of the side monitor electrode in the extending direction of the dicing line region 12, are set. Note that the distance b is illustrated in FIG. 3, and the length d is illustrated in FIG. 2.

As shown in FIG. 4, when 15 [μm]>b>1.15×d+6.88, preferably 10 [μm] b>1.15×d+6.88 is established, peeling of the coating film 4 is suppressed. Therefore, the semiconductor structure according to Embodiment 1 is configured to establish 15[μm]>b>1.15×d+6.88. Note that if this formula holds true, peeling of the coating film 4 will be suppressed even when the length d is greater than 100 μm.

### Summary of Embodiment 1

According to the method of manufacturing the semiconductor device according to Embodiment 1 as described above, the semiconductor structure in which the side monitor electrode 2 is provided on the dicing line region 12 is used. According to such a configuration, the ineffective region in the semiconductor substrate 1 can be reduced.

Further, in Embodiment 1, 15>b>1.15×d+6.88 is established between the distance b [μm], being the distance between the coating film 4 and the side monitor electrode 2 in plan view, and the length d [mm], being the length of the side monitor electrode 2 in the extending direction of the dicing line region 12 in plan view. According to such a configuration, the developer can be suppressed from remaining in a concave portion between the side monitor electrode 2 and the coating film 4, suppressing the coating film from peeling off. As a result, deterioration in reliability and appearance abnormalities of the semiconductor device can be suppressed.

Note that when the passivation film 3 is, for example, a glass coat film containing silicon nitride (SiN), the adhesion between the passivation film 3 and the coating film 4 can be enhanced more than the adhesion between the semiconductor substrate 1 and the coating film 4. As a consequence, even if the developer remains in the concave portion, peeling off of the coating film 4 due to the developer seeping into the gap between the passivation film 3 and the coating film 4 can be prevented.

Further, with the semiconductor substrate 1 composed of SiC, the ineffective region can be reduced in the expensive semiconductor substrate 1, thereby reducing the cost of the semiconductor device.

### Embodiment 2

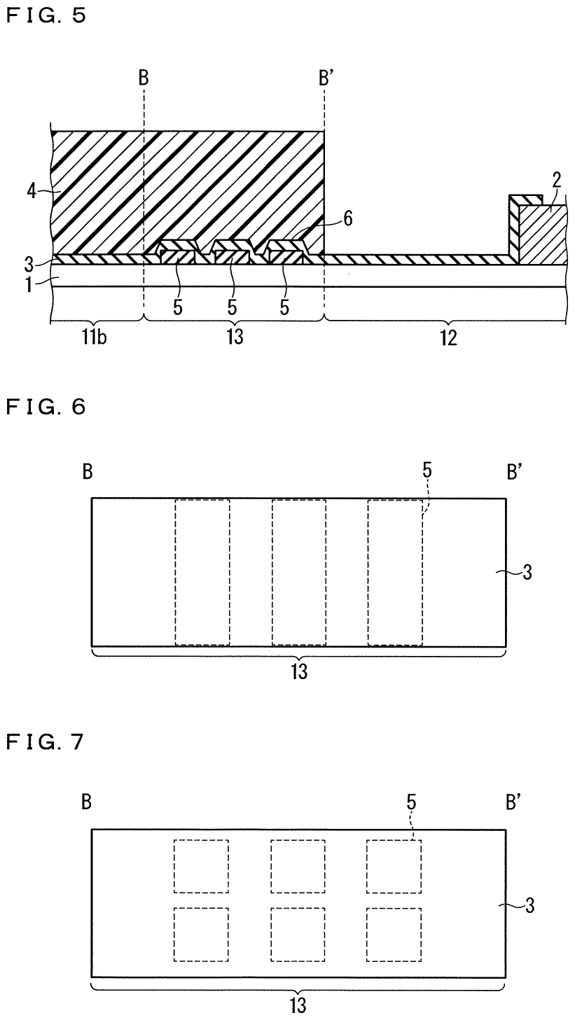

FIG. 5 is a cross-sectional view showing a configuration of a semiconductor structure according to Embodiment 2, and is a cross-sectional view corresponding to FIG. 3. In the semiconductor structure according to Embodiment 2, an extra region 13 is defined between the termination region 11b and the dicing line region 12. The extra region 13 is a region outside the depletion layer at the end portion of the semiconductor chip 11. The semiconductor substrate 1, the passivation film 3, and the coating film 4 are also provided in the extra region 13 as well as in the termination region 11b.

The semiconductor structure includes one or more insulating films 5 in addition to the configuration of FIG. 3. FIG. 6 is a plan view showing the configuration of the extra region 13. The insulating film 5 is provided only in the extra region 13 and between the passivation film 3 and the semiconductor substrate 1. With this configuration, as shown in FIG. 5, a concave-convex portion 6 is provided only in the extra region 13 and in the passivation film 3 and the coating film 4, the concave-convex portion 6 fitting into each other in cross-sectional view and corresponding to the shape of the insulating film 5. The number of concave-convex portions 6 may be one, or a plurality of concave-convex portions 6 may be provided at intervals. Note that the insulating film 5 is composed of, for example, tetra ethoxy silane (TEOS).

### Summary of Embodiment 2

According to the method of manufacturing the semiconductor device according to Embodiment 2 as described above, the concave-convex portion 6 is provided in the passivation film 3 and the coating film 4, the concave-convex portion 6 fitting into each other in cross-sectional view and corresponding to the shape of the insulating film 5. According to such a configuration, the surface area of the interface between the passivation film 3 and the coating film 4 can be increased, thereby enhancing the adhesion to each other. As a consequence, even if the developer remains in the concave portion, peeling off of the coating film 4 due to the developer seeping into the gap between the passivation film 3 and the coating film 4 is prevented.

Further, in Embodiment 2, the concave-convex portion 6 is provided only in the extra region 13. According to such a configuration, the extra region 13 can be effectively utilized.

### Modification

In FIGS. 5 and 6, although the plurality of insulating films 5 are arranged in a direction from the termination region 11b toward the dicing line region 12, the present invention is not limited thereto. For example, as shown in FIG. 7, the plurality of insulating films 5 may be arranged in both the direction from the termination region 11b toward the dicing line region 12 and the direction perpendicular thereto. Further, for example, the insulating film 5 may be provided continuously or intermittently so as to surround the extra region 13. Note that the number, size, and arrangement of the insulating films 5 are not limited to those described above.

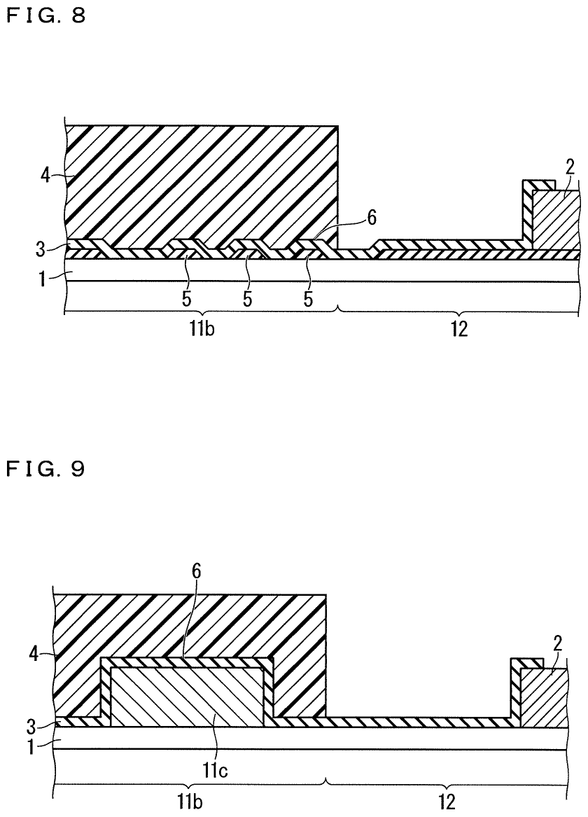

Further, in FIG. 5, the side surface of the insulating film 5 is perpendicular to the bottom surface of the insulating film 5. However, as shown in FIG. 8, the taper angle of the insulating film 5 may be less than 90° so that the insulating film 5 has a tapered shape that tapers upward in cross-sectional view. According to such a configuration, the shape of the concave-convex portion 6 between the passivation film 3 and the coating film 4 is made smooth, making it less likely that bubbles to be generated between the passivation film 3 and the coating film 4, thereby enhancing the adhesion between the passivation film 3 and the coating film 4.

Further, in Embodiment 2, the concave-convex portion 6 is provided only in the extra region 13. However, in case there is no need for effective utilization of the extra region 13, the concave-convex portion 6 may be provided in the termination region 11b . Further, as shown in FIG. 9, the concave-convex portion 6 may be provided in the passivation film 3 and the coating film 4 in cross-sectional view, the concave-convex portion 6 fitting into each other in cross-sectional view and corresponding to the shape of a front surface electrode 11c by providing the front surface electrode 11c of the semiconductor chip 11 instead of the insulating film 5. With such a configuration as well, the same effects as those in Embodiment 2 can be obtained.

It should be noted that Embodiments and Modification can be arbitrarily combined and Embodiments and Modification can be appropriately modified or omitted.

Hereinafter, the aspects of the present disclosure will be collectively described as Appendices.

### Appendix 1

A method of manufacturing a semiconductor device, comprising:
a preparation step of preparing a semiconductor structure in which a termination region of a semiconductor chip and a dicing line region adjacent to the termination region in plan view are defined; and
a dicing step in which dicing is performed on the dicing line region, wherein
the semiconductor structure includes
   a semiconductor substrate in which the termination region and the dicing line region are defined,
   a side monitor electrode provided on the semiconductor substrate in the dicing line region,
   a passivation film provided from an upper portion of the semiconductor substrate in the termination region to an upper portion of the side monitor electrode, and
   a coating film provided on the passivation film in the termination region,
a thickness of the side monitor electrode is smaller than a thickness of the coating film, and
15>b>1.15×d+6.88 is established between a distance b [μm], being a distance between the coating film and the side monitor electrode, and a length d [mm], being a length of the side monitor electrode in an extending direction of the dicing line region in plan view.

### Appendix 2

The method of manufacturing the semiconductor device according to Appendix 1, wherein
the distance b is greater than or equal to 7 μm, and the length d is greater than 100 μm.

### Appendix 3

The method of manufacturing the semiconductor device according to Appendix 1 or 2, wherein
the semiconductor structure further includes one or more insulating films provided between the passivation film and the semiconductor substrate, and
a concave-convex portion is provided in the passivation film and the coating film, the concave-convex portion fitting into each other in cross-sectional view and corresponding to a shape of the insulating film.

### Appendix 4

The method of manufacturing the semiconductor device according to Appendix 1 or 2, wherein
in the semiconductor structure, an extra region is further defined between the termination region and the dicing line region,
the semiconductor substrate, the passivation film, and the coating film are provided in the extra region,
the semiconductor structure further includes one or more insulating films provided between the passivation film and the semiconductor substrate, and
a concave-convex portion is provided only in the extra region and in the passivation film and the coating film, the concave-convex portion fitting into each other in cross-sectional view and corresponding to a shape of the insulating film.

### Appendix 5

The method of manufacturing the semiconductor device according to Appendix 3 or 4, wherein
the insulating film has a taper angle of less than 90°.

### Appendix 6

The method of manufacturing the semiconductor device according to any one of Appendices 1 to 5, wherein
the semiconductor structure further includes one or more front surface electrode provided between the passivation film and the semiconductor substrate, and
a concave-convex portion is provided in the passivation film and the coating film in cross-sectional view, the concave-convex portion fitting into each other in cross-sectional view and corresponding to a shape of the front surface electrode.

### Appendix 7

The method of manufacturing the semiconductor device according to any one of Appendices 1 to 6, wherein
the semiconductor substrate is composed of SiC.

### Appendix 8

The method of manufacturing the semiconductor device according to any one of Appendices 1 to 7, wherein
the preparation step includes a developing step of forming a pattern of the coating film.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a semiconductor device, comprising:
a preparation step of preparing a semiconductor structure in which a termination region of a semiconductor chip and a dicing line region adjacent to the termination region in plan view are defined; and
a dicing step in which dicing is performed on the dicing line region, wherein
the semiconductor structure includes
a semiconductor substrate in which the termination region and the dicing line region are defined,
a side monitor electrode provided on the semiconductor substrate in the dicing line region,
a passivation film provided from an upper portion of the semiconductor substrate in the termination region to an upper portion of the side monitor electrode, and
a coating film provided on the passivation film in the termination region,
a thickness of the side monitor electrode is smaller than a thickness of the coating film, and
15>b>1.15×d+6.88 is established between a distance b [μm], being a distance between the coating film and the side monitor electrode, and a length d [mm], being a length of the side monitor electrode in an extending direction of the dicing line region in plan view.

2. The method of manufacturing the semiconductor device according to claim 1, wherein
the distance b is greater than or equal to 7 μm, and the length d is greater than 100 μm.

3. The method of manufacturing the semiconductor device according to claim 1, wherein
the semiconductor structure further includes one or more insulating films provided between the passivation film and the semiconductor substrate, and
a concave-convex portion is provided in the passivation film and the coating film, the concave-convex portion fitting into each other in cross-sectional view and corresponding to a shape of the insulating film.

4. The method of manufacturing the semiconductor device according to claim 1, wherein
in the semiconductor structure, an extra region is further defined between the termination region and the dicing line region,
the semiconductor substrate, the passivation film, and the coating film are provided in the extra region,
the semiconductor structure further includes one or more insulating films provided between the passivation film and the semiconductor substrate, and
a concave-convex portion is provided only in the extra region and in the passivation film and the coating film, the concave-convex portion fitting into each other in cross-sectional view and corresponding to a shape of the insulating film.

5. The method of manufacturing the semiconductor device according to claim 3, wherein
the insulating film has a taper angle of less than 90°.

6. The method of manufacturing the semiconductor device according to claim 1, wherein
the semiconductor structure further includes one or more front surface electrode provided between the passivation film and the semiconductor substrate, and
a concave-convex portion is provided in the passivation film and the coating film in cross-sectional view, the concave-convex portion fitting into each other in cross-sectional view and corresponding to a shape of the front surface electrode.

7. The method of manufacturing the semiconductor device according to claim 1, wherein
the semiconductor substrate is composed of SiC.

8. The method of manufacturing the semiconductor device according to claim 1, wherein
the preparation step includes a developing step of forming a pattern of the coating film.
